(19) United States
(12) Patent Application Publication
(10) Pub. No.: US 2025/0210578 A1
(43) Pub. Date: Jun. 26, 2025

(54) SEMICONDUCTOR DEVICE

(71) Applicant: Rohm Co., Ltd., Kyoto-shi (JP)

(72) Inventor: Kenichi YOSHIMOCHI, Kyoto-shi (JP)

(21) Appl. No.: 19/077,846

(22) Filed: Mar. 12, 2025

Related U.S. Application Data
(63) Continuation of application No. PCT/JP2023/030657, filed on Aug. 25, 2023.

(30) Foreign Application Priority Data
Sep. 16, 2022 (JP) 2022-147744

(51) Int. Cl. H01L 23/00; H01L 23/31; H01L 23/495

(52) U.S. Cl. CPC H01L 24/37; H01L 23/3121; H01L 23/49513; H01L 24/40; H01L 2224/3701; H01L 2224/40247

(57) ABSTRACT

A semiconductor device includes a plurality of leads, a semiconductor element, and a sealing resin. The first lead includes a first main portion, and a plurality of first branch portions extending from the first main portion in a second direction, and aligned along the first direction. The first branch portion includes a first basal portion connected to the first main portion and a first connecting portion conductively bonded to a first electrode. A first width corresponding to a width of the first connecting portion in the first direction, is narrower than a second width corresponding to a width in the first direction, of a boundary between the first basal portion and the first main portion.

### TECHNICAL FIELD

The present disclosure relates to a semiconductor device.

### BACKGROUND ART

Semiconductor elements based on a III-V nitride compound semiconductor (hereinafter simply “nitride semiconductor”, where appropriate) such as gallium nitride (GaN) have recently been developed. JP-A-2018-82011 discloses a semiconductor element including the nitride semiconductor. This conventional semiconductor element includes an element main body constituted of a semiconductor, and a nitride semiconductor layer and an electrode, stacked on the side of the main face of the element main body. The electrode includes a source electrode, a drain electrode, and a gate electrode, located on the nitride semiconductor layer. This semiconductor element is constituted as a GaN-high electron mobility transistor (HEMT) element.

### BRIEF DESCRIPTION OF DRAWINGS

FIG. 1 is a plan view showing a semiconductor device according to a first embodiment of the present disclosure.

FIG. 2 is a partial plan view of the semiconductor device according to the first embodiment of the present disclosure.

FIG. 3 is a bottom view of the semiconductor device according to the first embodiment of the present disclosure.

FIG. 4 is a front view of the semiconductor device according to the first embodiment of the present disclosure.

FIG. 5 is a rear view of the semiconductor device according to the first embodiment of the present disclosure.

FIG. 6 is a left-side view of the semiconductor device according to the first embodiment of the present disclosure.

FIG. 7 is a right-side view of the semiconductor device according to the first embodiment of the present disclosure.

FIG. 8 is a cross-sectional view taken along a line VIII-VIII in FIG. 1.

FIG. 9 is a cross-sectional view taken along a line IX-IX in FIG. 1.

FIG. 10 is a cross-sectional view taken along a line X-X in FIG. 1.

FIG. 11 is a cross-sectional view taken along a line XI-XI in FIG. 1.

FIG. 12 is a partially enlarged plan view of the semiconductor device according to the first embodiment of the present disclosure.

FIG. 13 is a partially enlarged plan view showing a first variation of the semiconductor device according to the first embodiment of the present disclosure.

FIG. 14 is a partially enlarged plan view showing a second variation of the semiconductor device according to the first embodiment of the present disclosure.

FIG. 15 is a partially enlarged plan view showing a third variation of the semiconductor device according to the first embodiment of the present disclosure.

FIG. 16 is a plan view showing a semiconductor device according to a second embodiment of the present disclosure.

FIG. 17 is a cross-sectional view taken along a line XVII-XVII in FIG. 16.

FIG. 18 is a cross-sectional view taken along a line XVIII-XVIII in FIG. 16.

FIG. 19 is a cross-sectional view showing a first variation of the semiconductor device according to the second embodiment of the present disclosure.

FIG. 20 is a cross-sectional view showing a second variation of the semiconductor device according to the second embodiment of the present disclosure.

### DETAILED DESCRIPTION OF EMBODIMENTS

Hereafter, exemplary embodiments of the present disclosure will be described in detail, with reference to the drawings.

The terms “first”, “second”, “third”, and so forth used in the present disclosure merely serve as a label, and are not necessarily intended to specify an order with respect to the objects accompanied with these terms.

In the description of the present disclosure, the expression “an object A is formed in an object B”, and “an object A is formed on an object B” imply the situation where, unless otherwise specifically noted, “the object A is formed directly in or on the object B”, and “the object A is formed in or on the object B, with something else interposed between the object A and the object B”. Likewise, the expression “an object A is arranged in an object B”, and “an object A is arranged on an object B” imply the situation where, unless otherwise specifically noted, “the object A is arranged directly in or on the object B”, and “the object A is arranged in or on the object B, with something else interposed between the object A and the object B”. Further, the expression “an object A is located on an object B” implies the situation where, unless otherwise specifically noted, “the object A is located on the object B, in contact with the object B”, and “the object A is located on the object B, with something else interposed between the object A and the object B”. The expression “an object A is overlapping with an object B when viewed in a certain direction” implies the situation where, unless otherwise specifically noted, “the object A is overlapping with the entirety of the object B”, and “the object A is overlapping with a part of the object B”. Further, in the present disclosure, the expression “a face A is oriented (to one side or the other side) in a direction B” is not limited to the situation where the face A is orthogonal) (90° to the direction B, but includes the case where the face A is inclined with respect to the direction B.

### First Embodiment

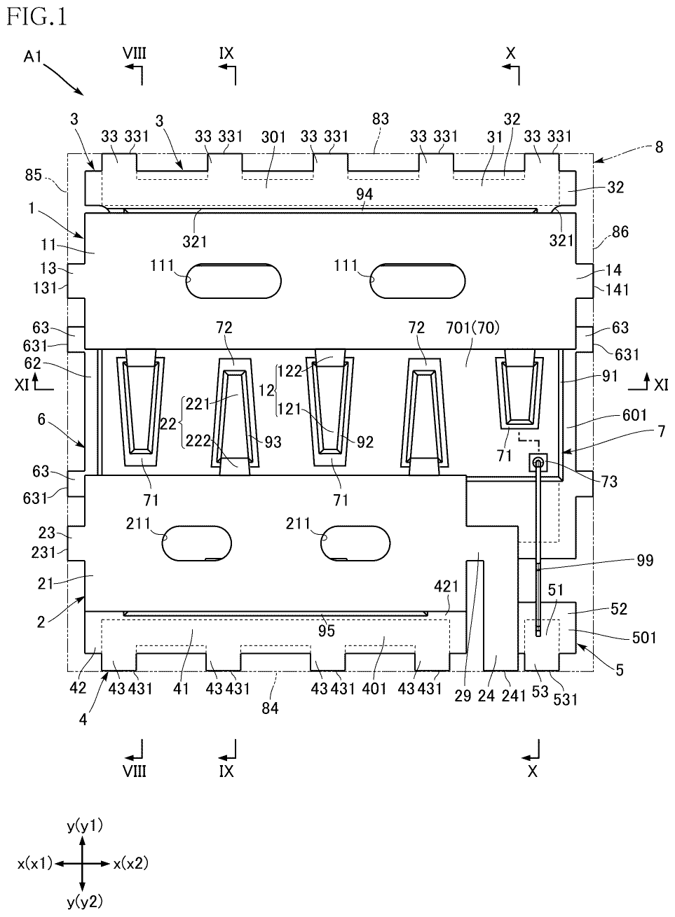

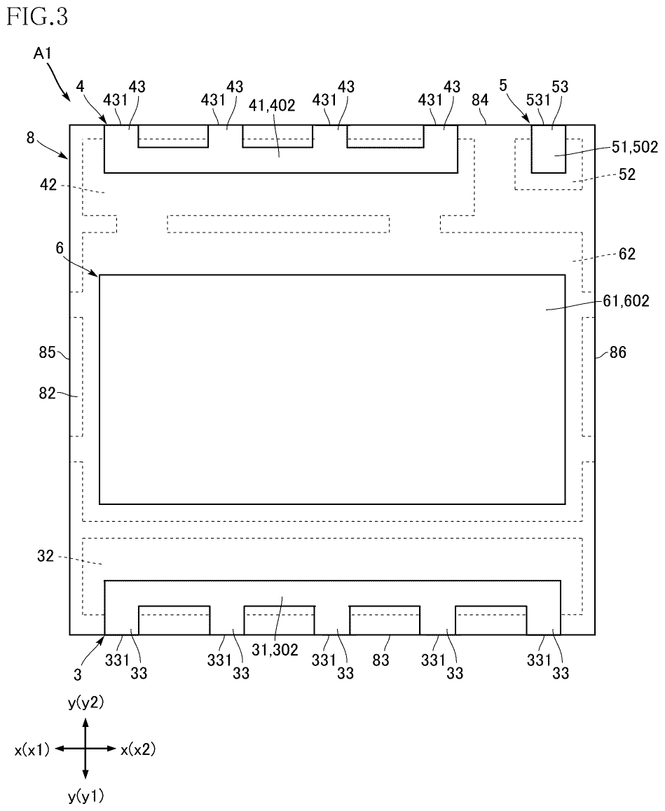

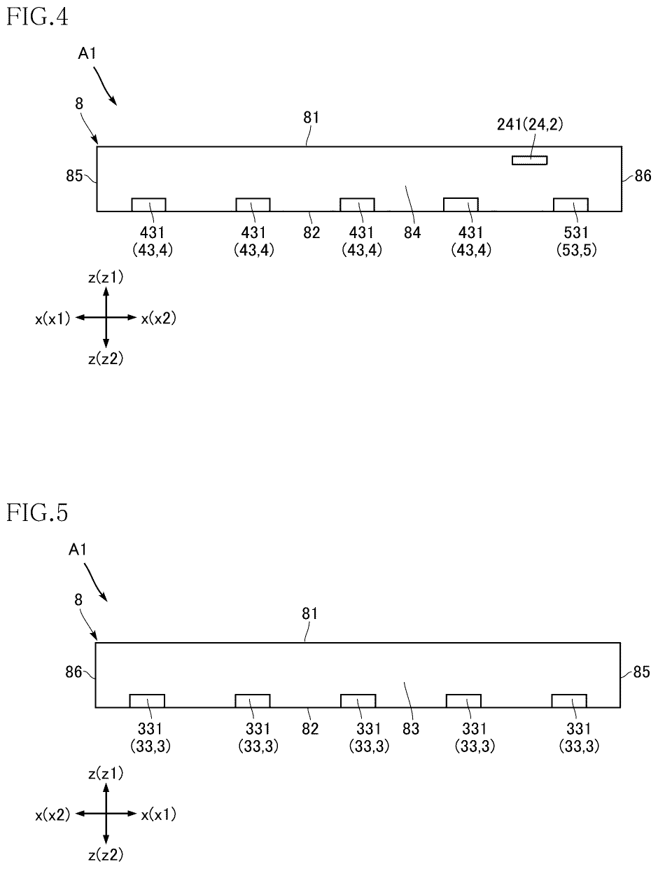

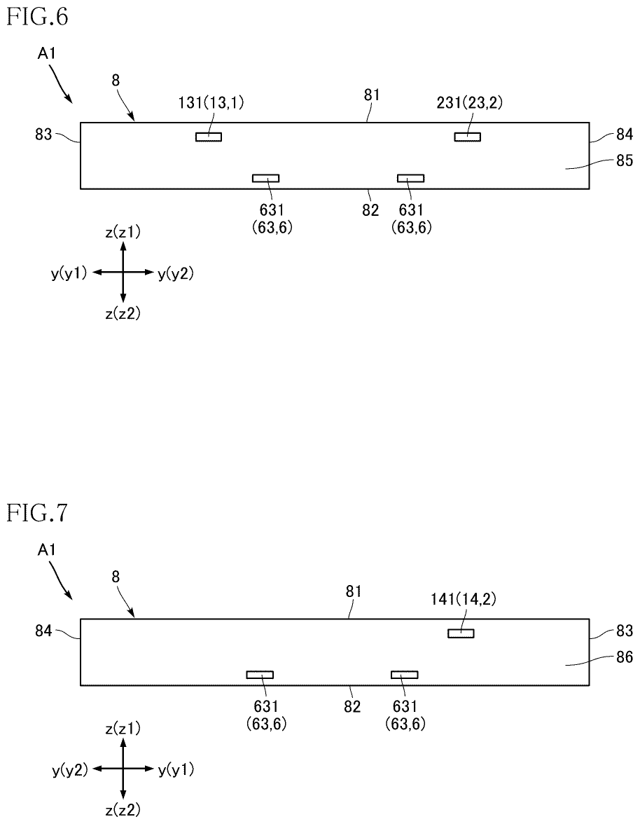

FIG. 1 to FIG. 12 illustrate a semiconductor device according to a first embodiment of the present disclosure. The semiconductor device A1 according to this embodiment includes a plurality of leads 1 to 6, a semiconductor element 7, a wire 99,and a sealing resin 8. The semiconductor device A1 is, for example, to be used for switching a current, when mounted on a circuit board. However, the specific purpose of use of the semiconductor device A1 is in no way limited.

In the mentioned drawings, a thickness direction in the present disclosure will be defined as thickness direction z. One side in the thickness direction z will be referred to as z1-side, and the opposite side of the z1-side in the z-direction will be referred to as z2-side. A direction orthogonal to the thickness direction z will be defined as first direction x. One side in the first direction x will be referred to as x1-side, and the opposite side of the x1-side will be referred to as x2-side. A direction orthogonal to the thickness direction z and the first direction x will be defined as second direction y. One side in the second direction y will be defined as y1-side, and the opposite side of the y1-side will be defined as y2-side.

### Leads 1 to 6

The plurality of leads 1 to 6 serve to perform such functions as supporting the semiconductor element 7, and forming conduction paths electrically connected to the semiconductor element 7, as appropriate. The plurality of leads 1 to 6 each include a metal such as copper (Cu), nickel (Ni), and iron (Fe). The plurality of leads 1 to 6 may be formed, for example, by performing a processing selected from punching, bending, and etching, on a metal plate material. Further, a plated layer of silver (Ag), Ni, or gold (Au) may be formed, as necessary, on a predetermined position on each of the plurality of leads 1 to 6.

In this embodiment, the plurality of leads 1 to 6 will be referred to as first lead 1, second lead 2, third lead 3, fourth lead 4, fifth lead 5, and island lead 6, respectively. In other words, the plurality of leads 1 to 6 include the first lead 1, the second lead 2, the third lead 3, the fourth lead 4, the fifth lead 5, and the island lead 6. As will be subsequently described, the fourth lead 4 and the island lead 6 are connected to each other, in this embodiment. The leads 1 to 6 may each be formed as an independent piece, or connected to another, depending on the configuration of electrical conduction. In addition, the following description is based on the assumption that the first lead 1 and the second lead 2 are formed by punching and bending a metal plate material, and the third lead 3, the fourth lead 4, the fifth lead 5, and the island lead 6 are formed by performing etching on a metal plate material.

### Island Lead 6

As shown in FIG. 1 to FIG. 3 and FIG. 8 to FIG. 11, the island lead 6 includes an obverse face 601, a reverse face 602, a thick portion 61, a thin portion 62, and a plurality of protruding portions 63. The obverse face 601 is oriented to the z1-side of the z-direction and, in the illustrated example, formed as a smooth face perpendicular to the z-direction. Here, the island lead 6 may include, as appropriate, a recess or a groove recessed from the obverse face 601. The reverse face 602 is oriented to the z2-side of the z-direction, in other words to the opposite side of the obverse face 601. In the illustrated example, the reverse face 602 is formed as a smooth face perpendicular to the z-direction. Here, a plated layer formed of Ni or titanium (Ti) may be provided on the reverse face 602, as appropriate.

The thick portion 61 corresponds to the portion where the obverse face 601 and the reverse face 602 overlap, when viewed in the z-direction and, in the illustrated example, has a rectangular shape when viewed in the z-direction. However, the shape of the thick portion 61 is in no way limited. The thickness of the thick portion 61 in the z-direction corresponds to the distance between the obverse face 601 and the reverse face 602. The thin portion 62 corresponds to the portion overlapping with the obverse face 601, but deviated from the reverse face 602, when viewed in the z-direction and, in the illustrated example, continuously extends from the thick portion 61 along the respective sides in the x-direction and the respective sides in the y-direction, when viewed in the z-direction. The thickness of the thin portion 62 in the z-direction is smaller than the distance between the obverse face 601 and the reverse face 602. The thickness of the thick portion 61 and the thickness of the thin portion 62 are in no way limited. For example, the thickness of the thick portion 61 may be approximately 0.2 mm to 0.5 mm, and the thickness of the thin portion 62 may be approximately 0.1 mm to 0.4 mm. In the illustrated example, the portion of the thin portion 62, extending from the thick portion 61 to the y1-side of the y-direction, is larger than the portion extending to the y2-side.

The plurality of protruding portions 63 each protrude from the edge of the thin portion 62. In the illustrated example, the plurality of protruding portions 63 protrude from the thin portion 62 to both sides in the x-direction. The number of pieces of the protruding portion 63 is in no way limited, and may be two or more, or one. In the illustrated example, two protruding portions 63 are formed on the x1-side of the x-direction, and two protruding portions 63 are formed on the x2-side. The protruding portion 63 includes an end face 631. The end face 631 is oriented to the side opposite to the thin portion 62 in the x-direction, in other words to the outer side in the x-direction. As illustrated, the end face 631 is perpendicular to the x-direction. The two end faces 631 on the x1-side of the x-direction are located at the same (or generally the same) position, in the x-direction. Likewise, the two end faces 631 on the x2-side of the x-direction are located at the same (or generally the same) position, in the x-direction.

### First Lead 1

As shown in FIG. 1, FIG. 7, and FIG. 8 to FIG. 12, the first lead 1 is located on the z1-side of the z-direction, with respect to the third lead 3, the fourth lead 4, the fifth lead 5, and the island lead 6. The first lead 1 according to this embodiment includes a first main portion 11, a plurality of first branch portions 12, a first protruding portion 13, a third protruding portion 14, and a first upright portion 15.

The first main portion 11 is a plate-shaped portion extending along an xy-plane and, in the illustrated example, has a generally rectangular shape having the long sides extending in the x-direction. In the illustrated example, the first main portion 11 includes through holes 111. The through hole 111 is formed so as to penetrate through the first main portion 11 in the z-direction. The number of pieces of the through hole 111 is in no way limited, and may be one, or two or more. In the illustrated example, the first main portion 11 includes two through holes 111. The shape of the through hole 111 is in no way limited, but may be appropriately selected from circular, elliptical, rectangular, and polygonal. In the illustrated example, the through hole 111 has an elliptical shape, with the major axis extending in the x-direction, when viewed in the z-direction.

The plurality of first branch portions 12 each extend from the first main portion 11 to the y2-side of the y-direction. The number of pieces of the first branch portion 12 is in no way limited but, in the illustrated example, three first branch portions 12 are provided. The plurality of first branch portions 12 are aligned along the x-direction. The first branch portions 12 each include a first connecting portion 121 and a first basal portion 122.

The first connecting portion 121 is located on the y2-side of the y-direction, with respect to the first main portion 11. The first connecting portion 121 is located on the z2-side of the z-direction, with respect to the first main portion 11. The shape of the first connecting portion 121 is in no way limited but, in the illustrated example, the first connecting portion 121 is elongate in the y-direction, when viewed in the z-direction. The first connecting portion 121 is perpendicular to the z-direction.

The first basal portion 122 is located between the first connecting portion 121 and the first main portion 11, and connected to the first connecting portion 121 and the first main portion 11. The first basal portion 122 is inclined so as to come closer to the semiconductor element 7 in the z-direction (toward the z2-side), in the direction from the first main portion 11 toward the first connecting portion 121 in the y-direction (from the y1-side toward the y2-side).

In the illustrated example, the three first branch portions 12 include the first branch portions 12, different in length in the y-direction from each other. The first branch portion 12 located at the x2-side end in the x-direction is shorter in length in the y-direction, than the other first branch portions 12. The first branch portion 12 located at the x2-side end in the x-direction is located close to a third electrode 73 and the wire 99, to be subsequently described. However, the plurality of first branch portions 12 may all have the same length.

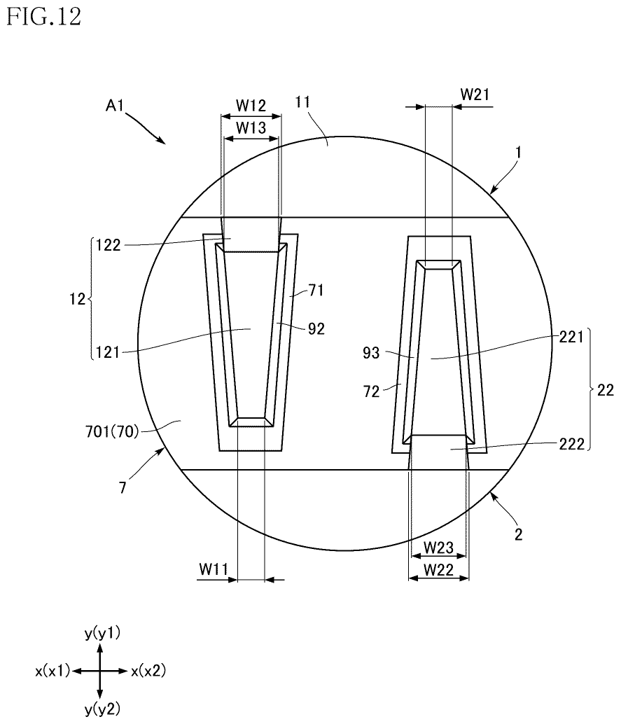

As shown in FIG. 12, a first width W11, corresponding to the width in the first direction x, of the distal end portion of the first connecting portion 121 on the y2-side of the y-direction, is larger than a second width W12, corresponding to the width in the first direction x, of the boundary between the first basal portion 122 and the first main portion 11. In this embodiment, the first connecting portion 121 is formed so as to be narrower in the first direction x, in the direction from the distal end portion on the y2-side of the y-direction, toward the first basal portion 122. The first connecting portion 121 is exclusively formed of the first tapered portion in the present disclosure.

In the illustrated example, in addition, a third width W13, corresponding to the width of the boundary between the first basal portion 122 and the first connecting portion 121 in the first direction x, is narrower than the second width W12. In the illustrated example, the first basal portion 122 has a tapered shape that becomes wider in the first direction x, in the direction from the first connecting portion 121 (y2-side of the y-direction) toward the first main portion 11 (y1-side). Further, the illustrated example of the first branch portion 12 has, as a whole, a tapered shape that becomes wider in the first direction x, in the direction from the y2-side of the y-direction toward the y1-side. In other words, the first connecting portion 121 and the first basal portion 122 form a continuous tapered shape, when viewed in the z-direction.

The first protruding portion 13 protrudes from the first main portion 11. The first protruding portion 13 protrudes toward the x1-side of the x-direction, from the edge of the first main portion 11 on the x1-side. The first protruding portion 13 includes a first end face 131. The first end face 131 is oriented to the side opposite to the first main portion 11 in the x-direction, in other words to the x1-side, which is the outer side in the x-direction. As illustrated, the first end face 131 is perpendicular to the x-direction. The first end face 131 is located at the same (or generally the same) position in the x-direction, as the plurality of end faces 631 on the x1-side of the x-direction.

The third protruding portion 14 protrudes from the first main portion 11. The third protruding portion 14 protrudes toward the x2-side of the x-direction, from the edge of the first main portion 11 on the x2-side. The third protruding portion 14 includes a third end face 141. The third end face 141 is oriented to the side opposite to the first main portion 11 in the x-direction, in other words to the x2-side, which is the outer side in the x-direction. As illustrated, the third end face 141 is perpendicular to the x-direction. The third end face 141 is located at the same (or generally the same) position in the x-direction, as the plurality of end faces 631 on the x2-side of the x-direction.

The first upright portion 15 is connected to the edge of the first main portion 11 on the y1-side of the y-direction, on the opposite side of the first branch portion 12. The first upright portion 15 extends from the first main portion 11 toward the z2-side of the z-direction. The shape of the first upright portion 15 is in no way limited but, in the illustrated example, the first upright portion 15 has a rectangular shape having the long sides extending in the x-direction. In the illustrated example, the center of the first upright portion 15 in the x-direction is located at the same (or generally the same) position as the center of the first main portion 11 in the x-direction.

As shown in FIG. 8 to FIG. 10, the end portion on the z2-side of the z-direction, of the first upright portion 15 of the first lead 1, is conductively bonded to the third lead 3, via a fourth conductive bonding portion 94. The fourth conductive bonding portion 94 may be formed of, for example, solder, Ag paste, sintered Ag, or sintered Cu.

### Second Lead 2

As shown in FIG. 1, FIG. 7 and FIG. 8 to FIG. 12, the second lead 2 is located on the z1-side of the z-direction, with respect to the third lead 3, the fourth lead 4, the fifth lead 5, and the island lead 6. The second lead 2 is located on the y2-side of the y-direction, with respect to the first lead 1. In this embodiment, the second lead 2 includes a second main portion 21, a plurality of second branch portions 22, a second protruding portion 23, a fourth protruding portion 24, a second upright portion 25, and an intermediate portion 29.

The second main portion 21 is a plate-shaped portion extending along an xy-plane and, in the illustrated example, has a generally rectangular shape having the long sides extending in the x-direction. The first main portion 11 and the second main portion 21 are located on opposite sides in the y-direction, across the semiconductor element 7. In the illustrated example, the second main portion 21 includes through holes 211. The through hole 211 is formed so as to penetrate through the second main portion 21 in the z-direction. The number of pieces of the through hole 211 is in no way limited, and may be one, or two or more. In the illustrated example, the second main portion 21 includes two through holes 211. The shape of the through hole 211 is in no way limited, but may be appropriately selected from circular, elliptical, rectangular, and polygonal. In the illustrated example, the through hole 211 has an elliptical shape, with the major axis extending in the x-direction, when viewed in the z-direction. In this embodiment, the second main portion 21 is located at the same (or generally the same) position in the z-direction, as the first main portion 11.

The plurality of second branch portions 22 each extend from the second main portion 21 to the y1-side of the y-direction. The number of pieces of the second branch portion 22 is in no way limited but, in the illustrated example, two second branch portions 22 are provided. The plurality of second branch portions 22 are aligned along the x-direction. The second branch portions 22 each include a second connecting portion 221 and a second basal portion 222.

The second connecting portion 221 is located on the y1-side of the y-direction, with respect to the second main portion 21. The second connecting portion 221 is located on the z2-side of the z-direction, with respect to the second main portion 21. The shape of the second connecting portion 221 is in no way limited but, in the illustrated example, the second connecting portion 221 is elongate in the y-direction, when viewed in the z-direction. The second connecting portion 221 is perpendicular to the z-direction.

The second basal portion 222 is located between the second connecting portion 221 and the second main portion 21, and connected to the second connecting portion 221 and the second main portion 21. The second basal portion 222 is inclined so as to come closer to the semiconductor element 7 in the z-direction (toward the z2-side), in the direction from the second main portion 21 toward the second connecting portion 221 in the y-direction (from the y2-side toward the y1-side).

In the illustrated example, the two second branch portions 22 have the same length in the y-direction. Alternatively, the plurality of second branch portions 22 may be different in length in the y-direction, from each other.

As shown in FIG. 12, a fourth width W21, corresponding to the width in the first direction x, of the distal end portion of the second connecting portion 221 on the y1-side of the y-direction, is larger than a fifth width W22, corresponding to the width in the first direction x, of the boundary between the second basal portion 222 and the second main portion 21. In this embodiment, the second connecting portion 221 is formed so as to be narrower in the first direction x, in the direction from the distal end portion on the y1-side of the y-direction, toward the second basal portion 222. The second connecting portion 221 is exclusively formed of the second tapered portion in the present disclosure.

In the illustrated example, in addition, a sixth width W23, corresponding to the width of the boundary between the second basal portion 222 and the second connecting portion 221 in the first direction x, is narrower than the fifth width W22. In the illustrated example, the second basal portion 222 has a tapered shape that becomes wider in the first direction x, in the direction from the second connecting portion 221 (y1-side of the y-direction) toward the second main portion 21 (y2-side). Further, the illustrated example of the second branch portion 22 has, as a whole, a tapered shape that becomes wider in the first direction x, in the direction from the y1-side of the y-direction toward the y2-side. In other words, the second connecting portion 221 and the second basal portion 222 form a continuous tapered shape, when viewed in the z-direction.

The second protruding portion 23 protrudes from the second main portion 21. The second protruding portion 23 protrudes toward the x1-side of the x-direction, from the edge of the second main portion 21 on the x1-side. The second protruding portion 23 includes a second end face 231. The second end face 231 is oriented to the side opposite to the second main portion 21 in the x-direction, in other words to the x1-side, which is the outer side in the x-direction. As illustrated, the second end face 231 is perpendicular to the x-direction. The second end face 231 is located at the same (or generally the same) position in the x-direction, as the first end face 131 and the end face 631 on the x1-side of the x-direction.

The fourth protruding portion 24 is connected to the second main portion 21, via the intermediate portion 29. The intermediate portion 29 is shorter in length in the y-direction, than the second main portion 21 and the fourth protruding portion 24. Thus, the configuration of the fourth protruding portion 24 in the present disclosure includes a form connected to the second main portion 21 via another portion, without limitation to a form directly connected to the second main portion 21. This also applies to the second protruding portion 23. In addition, the respective configurations of the first protruding portion 13 and the third protruding portion 14 also include a form connected to the first main portion 11 via another portion, without limitation to a form directly connected to the first main portion 11. The fourth protruding portion 24 extends along the y-direction. The fourth protruding portion 24 includes a fourth end face 241. The fourth end face 241 is oriented to the side opposite to the second main portion 21 in the y-direction, in other words to the y2-side, which is the outer side in the y-direction. As illustrated, the fourth end face 241 is perpendicular to the y-direction.

The second upright portion 25 is connected to the edge of the second main portion 21 on the y2-side of the y-direction, on the opposite side of the second branch portion 22. The second upright portion 25 extends from the second main portion 21 toward the z2-side of the z-direction. The shape of the second upright portion 25 is in no way limited but, in the illustrated example, the second upright portion 25 has a rectangular shape having the long sides extending in the x-direction. In the illustrated example, the center of the second upright portion 25 in the x-direction is located at the same (or generally the same) position as the center of the second main portion 21 in the x-direction.

As shown in FIG. 8 to FIG. 10, the end portion on the z2-side of the z-direction, of the second upright portion 25 of the second lead 2, is conductively bonded to the fourth lead 4, via a fifth conductive bonding portion 95. The fifth conductive bonding portion 95 may be formed of, for example, solder.

### Third Lead 3

As shown in FIG. 1 to FIG. 3, the third lead 3 is located on the y1-side of the y-direction, with respect to the island lead 6, with a spacing therebetween. The center of the third lead 3 in the x-direction is located at the same (or generally the same) position in the x-direction, as the center of the island lead 6 in the x-direction. As shown in FIG. 1 to FIG. 3 and FIG. 8 to FIG. 10, the third lead 3 includes an obverse face 301, a reverse face 302, a thick portion 31, a thin portion 32, and a plurality of protruding portions 33.

The obverse face 301 is oriented to the z1-side of the z-direction and, in the illustrated example, formed as a smooth face perpendicular to the z-direction. Here, the third lead 3 may include, as appropriate, a recess or a groove recessed from the obverse face 301. The above-mentioned first upright portion 15 is bonded to the obverse face 301, via the fourth conductive bonding portion 94. The reverse face 302 is oriented to the z2-side of the z-direction, in other words to the opposite side of the obverse face 301. In the illustrated example, the reverse face 302 is formed as a smooth face perpendicular to the z-direction. Here, a plated layer formed of Ni or Ti may be provided on the reverse face 302, as appropriate. In this embodiment, the obverse face 301 is located at the same (or generally the same) position in the z-direction as the obverse face 601, and the reverse face 302 is located at the same (or generally the same) position in the z-direction as the reverse face 602.

The thick portion 31 corresponds to the portion where the obverse face 301 and the reverse face 302 overlap, when viewed in the z-direction. In the illustrated example, the thick portion 31 has a rectangular shape having the long sides extending in the x-direction, when viewed in the z-direction. The shape of the thick portion 31 is in no way limited. The thickness of the thick portion 31 in the z-direction corresponds to the distance between the obverse face 301 and the reverse face 302. The thin portion 32 corresponds to the portion overlapping with the obverse face 301, but deviated from the reverse face 302, when viewed in the z-direction. In the illustrated example, the thin portion 32 continuously extends from the thick portion 31 along the respective sides in the x-direction and to the y2-side of the y-direction, when viewed in the z-direction. In addition, the thin portion 32 includes a portion continuously extending from the thick portion 31 to the y1-side of the y-direction, when viewed in the z-direction, and this portion is located between the protruding portions 33 adjacent to each other, in the x-direction. The thickness of the thin portion 32 in the z-direction is smaller than the distance between the obverse face 301 and the reverse face 302. The thickness of the thick portion 31 and the thickness of the thin portion 32 are in no way limited. In this embodiment, the thickness of the thick portion 31 is the same (or generally the same) as the thickness of the thick portion 61, and the thickness of the thin portion 32 is the same (or generally the same) as the thickness of the thin portion 62.

The plurality of protruding portions 33 each protrude from the edge of the thick portion 31. In the illustrated example, the plurality of protruding portions 33 protrude to the y1-side of the y-direction, from the thick portion 31. The number of pieces of the protruding portion 33 is in no way limited, and may be two or more, or one. In the illustrated example, four protruding portions 33 are provided. The protruding portion 33 includes an end face 331. The end face 331 is oriented to the side opposite to the thick portion 31 in the y-direction, in other words to the y1-side which is the outer side in the y-direction. The illustrated example of the end face 331 is perpendicular to the y-direction. The plurality of end faces 331 are located at the same (or generally the same) position as each other, in the y-direction.

### Fourth Lead 4

As shown in FIG. 1 to FIG. 3, the fourth lead 4 is located on the y2-side of the y-direction, with respect to the island lead 6. The center of the fourth lead 4 in the x-direction is located on the x1-side of the x-direction, with respect to the center of the island lead 6 in the x-direction. In the semiconductor device A1, the fourth lead 4 and the island lead 6 are connected via an intermediate portion 49. Instead, the fourth lead 4 may be separated from the island lead 6. As shown in FIGS. 1 to 3 and FIG. 8 to FIG. 10, the fourth lead 4 includes an obverse face 401, a reverse face 402, a thick portion 41, a thin portion 42, and a plurality of protruding portions 43.

The obverse face 401 is oriented to the z1-side of the z-direction and, in the illustrated example, formed as a smooth face perpendicular to the z-direction. Here, the fourth lead 4 may include, as appropriate, a recess or a groove recessed from the obverse face 401. The above-mentioned second upright portion 25 is bonded to the obverse face 401, via the fifth conductive bonding portion 95. The reverse face 402 is oriented to the z2-side of the z-direction, in other words to the opposite side of the obverse face 401. In the illustrated example, the reverse face 402 is formed as a smooth face perpendicular to the z-direction. Here, a plated layer formed of Ni or Ti may be provided on the reverse face 402, as appropriate. In this embodiment, the obverse face 401 is located at the same (or generally the same) position in the z-direction as the obverse face 601, and the reverse face 402 is located at the same (or generally the same) position in the z-direction as the reverse face 602.

The thick portion 41 corresponds to the portion where the obverse face 401 and the reverse face 402 overlap, when viewed in the z-direction. In the illustrated example, the thick portion 41 has a rectangular shape having the long sides extending in the x-direction, when viewed in the z-direction. Here, the shape of the thick portion 41 is in no way limited. The thickness of the thick portion 41 in the z-direction corresponds to the distance between the obverse face 401 and the reverse face 402. In this embodiment, the thick portion 41 is smaller in size in the x-direction, than the thick portion 31. The thin portion 42 corresponds to the portion overlapping with the obverse face 401, but deviated from the reverse face 402, when viewed in the z-direction. In the illustrated example, the thin portion 42 continuously extends from the thick portion 41 along the respective sides in the x-direction and to the y1-side of the y-direction, when viewed in the z-direction. In addition, the thin portion 42 includes a portion continuously extending from the thick portion 41 to the y2-side of the y-direction, when viewed in the z-direction, and this portion is located between the protruding portions 43 adjacent to each other, in the x-direction. The thickness of the thin portion 42 in the z-direction is smaller than the distance between the obverse face 401 and the reverse face 402. The thickness of the thick portion 41 and the thickness of the thin portion 42 are in no way limited. In this embodiment, the thickness of the thick portion 41 is the same (or generally the same) as the thickness of the thick portion 61, and the thickness of the thin portion 42 is the same (or generally the same) as the thickness of the thin portion 62.

The plurality of protruding portions 43 each protrude from the edge of the thick portion 41. In the illustrated example, the plurality of protruding portions 43 protrude to the y2-side of the y-direction, from the thick portion 41. The number of pieces of the protruding portion 43 is in no way limited, and may be two or more, or one. In the illustrated example, three protruding portions 43 are provided. The three protruding portions 43 are located at the same (or generally the same) position in the x-direction, as the three protruding portions 33 located on the x1-side of the x-direction, out of the plurality of protruding portions 33. The protruding portion 43 includes an end face 431. The end face 431 is oriented to the side opposite to the thick portion 41 in the y-direction, in other words to the y2-side which is the outer side in the y-direction. The illustrated example of the end face 431 is perpendicular to the y-direction. The plurality of end faces 431 are located at the same (or generally the same) position as each other, in the y-direction. In addition, the plurality of end faces 431 are located at the same (or generally the same) position in the y-direction, as the fourth end face 241.

### Fifth Lead 5

As shown in FIG. 1 to FIG. 3, the fifth lead 5 is located on the y2-side of the y-direction, with respect to the island lead 6. The center of the fifth lead 5 in the x-direction is located on the x2-side of the x-direction, with respect to the center of the island lead 6 in the x-direction. The fifth lead 5 is located on the x2-side of the x-direction, with respect to the fourth lead 4. As shown in FIGS. 1 to 3 and FIG. 10, the fifth lead 5 includes an obverse face 501, a reverse face 502, a thick portion 51, a thin portion 52, and a plurality of protruding portions 53.

The obverse face 501 is oriented to the z1-side of the z-direction and, in the illustrated example, formed as a smooth face perpendicular to the z-direction. Here, the fifth lead 5 may include, as appropriate, a recess or a groove recessed from the obverse face 501. To the obverse face 501, the wire 99 is bonded. The reverse face 502 is oriented to the z2-side of the z-direction, in other words to the opposite side of the obverse face 501. In the illustrated example, the reverse face 502 is formed as a smooth face perpendicular to the z-direction. Here, a plated layer formed of Ni or Ti may be provided on the reverse face 502, as appropriate. In this embodiment, the obverse face 501 is located at the same (or generally the same) position in the z-direction as the obverse face 601, and the reverse face 502 is located at the same (or generally the same) position in the z-direction as the reverse face 602.

The thick portion 51 corresponds to the portion where the obverse face 501 and the reverse face 502 overlap, when viewed in the z-direction. In the illustrated example, the thick portion 51 has a rectangular shape, when viewed in the z-direction. Here, the shape of the thick portion 51 is in no way limited. The thickness of the thick portion 51 in the z-direction corresponds to the distance between the obverse face 501 and the reverse face 502. In this embodiment, the thick portion 51 is smaller in size in the x-direction, than the thick portion 31 and the thick portion 41. The thin portion 52 corresponds to the portion overlapping with the obverse face 501, but deviated from the reverse face 502, when viewed in the z-direction. In the illustrated example, the thin portion 52 continuously extends from the thick portion 51 along the respective sides in the x-direction and to the y1-side of the y-direction, when viewed in the z-direction. The thickness of the thin portion 52 in the z-direction is smaller than the distance between the obverse face 501 and the reverse face 502. The thickness of the thick portion 51 and the thickness of the thin portion 52 are in no way limited. In this embodiment, the thickness of the thick portion 51 is the same (or generally the same) as the thickness of the thick portion 61, and the thickness of the thin portion 52 is the same (or generally the same) as the thickness of the thin portion 62.

The protruding portion 53 protrudes from the edge of the thick portion 51. In the illustrated example, the protruding portion 53 protrudes to the y2-side of the y-direction, from the thick portion 51. The number of pieces of the protruding portion 53 is in no way limited, and may be two or more, or one. In the illustrated example, one protruding portion 53 is provided. The protruding portion 53 is located at the same (or generally the same) position in the x-direction, as the protruding portion 33 located at the farthest end on the x1-side of the x-direction, out of the plurality of protruding portions 33. The protruding portion 53 includes an end face 531. The end face 531 is oriented to the side opposite to the thick portion 51 in the y-direction, in other words to the y2-side which is the outer side in the y-direction. The illustrated example of the end face 531 is perpendicular to the y-direction. The end face 531 is located at the same (or generally the same) position in the y-direction, as the fourth end face 241 and the plurality of end faces 431.

### Semiconductor Element 7

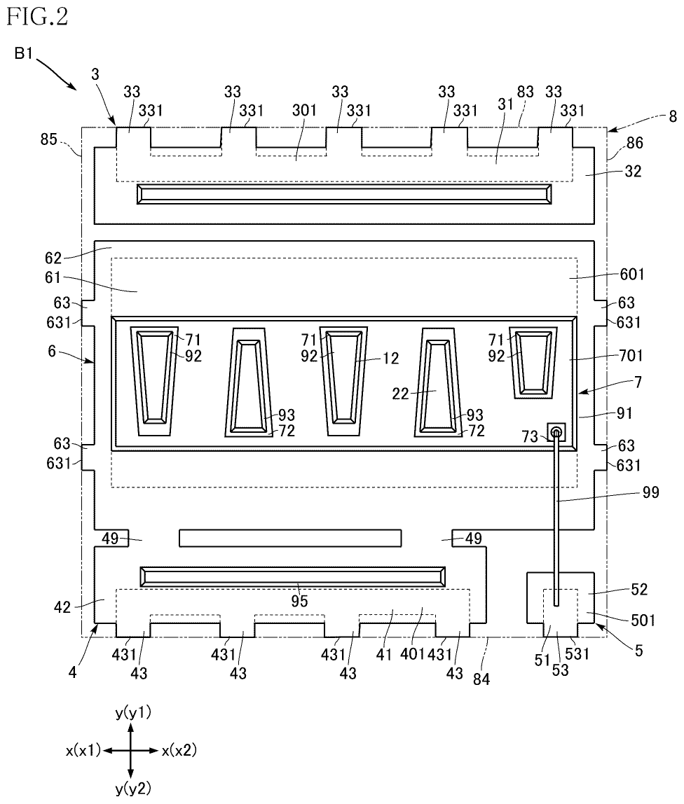

The semiconductor element 7 serves to perform the electrical functions of the semiconductor device A1. The specific configuration of the semiconductor element 7 is in no way limited but, this embodiment, the semiconductor element 7 is a transistor including a nitride semiconductor. To be more specific, the semiconductor element 7 is a GaN high electron mobility transistor (HEMT) element, including gallium nitride (GaN). Without limitation to the element including the nitride semiconductor, the semiconductor element 7 may be constituted of a different semiconductor including silicon (Si) or silicon carbide (SiC). Further, the semiconductor element 7 may be a transistor of different types, such as a metal-oxide-semiconductor field effect transistor (MOSFET), and an insulated gate bipolar transistor (IGBT), without limitation to the HEMT. The semiconductor element 7 is mounted on the thick portion 61 of the island lead 6. As shown in FIG. 1, FIG. 2, and FIG. 8 to FIG. 12, the semiconductor element 7 includes an element main body 70, a plurality of first electrodes 71, a plurality of second electrodes 72, and a third electrode 73.

On the element main body 70, for example, a substrate layer, a buffer layer, and a nitride layer (none shown) are stacked. The element main body 70 includes an element obverse face 701 and an element reverse face 702. The element obverse face 701 is oriented to the z1-side of the z-direction, and the element reverse face 702 is oriented t the z2-side of the z-direction, in other words to the opposite side of the element obverse face 701. In the illustrated example, a metal layer is formed on the element reverse face 702. As shown in FIG. 12 to FIG. 14, the metal layer and the obverse face 601 of the island lead 6 are bonded to each other, via a first conductive bonding portion 91. The first conductive bonding portion 91 is, for example, formed of solder, Ag paste, sintered Ag, or sintered Cu. Although the mentioned metal layer is provided for the bonding performance by the first conductive bonding portion 91, such metal layer may be excluded. Alternatively, the metal layer may be set to be equipotential to the second electrode 72, for example. In the illustrated example, the semiconductor element 7 is located so as to overlap with a part of the thick portion 61 of the island lead 6, and a part of the thin portion 62, when viewed in the z-direction.

The plurality of first electrodes 71, the plurality of second electrodes 72, and the third electrode 73 are located on the element obverse face 701. The number of pieces of the plurality of first electrodes 71 and the number of pieces of the plurality of second electrodes 72 are in no way limited. In the illustrated example, three first electrodes 71 and two second electrodes 72 are provided. The number of pieces of the plurality of first electrodes 71 and the number of pieces of the plurality of first branch portions 12 are the same, and the number of pieces of the plurality of second electrodes 72 and the number of pieces of the plurality of second branch portions 22 are the same. The first electrode 71 acts as a drain electrode. The second electrode 72 acts as a source electrode. The plurality of first electrodes 71 and the plurality of second electrodes 72 are alternately aligned along the x-direction. The shape of the first electrode 71 and the second electrode 72 is in no way limited. In the illustrated example, these electrodes have a shape elongate in the y-direction, more specifically a tapered shape elongate in the y-direction.

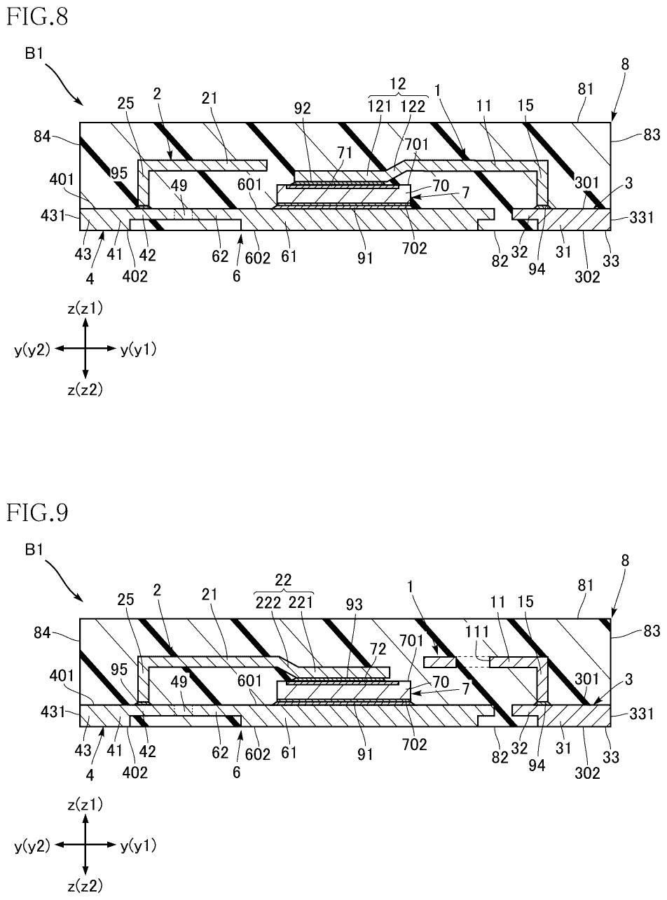

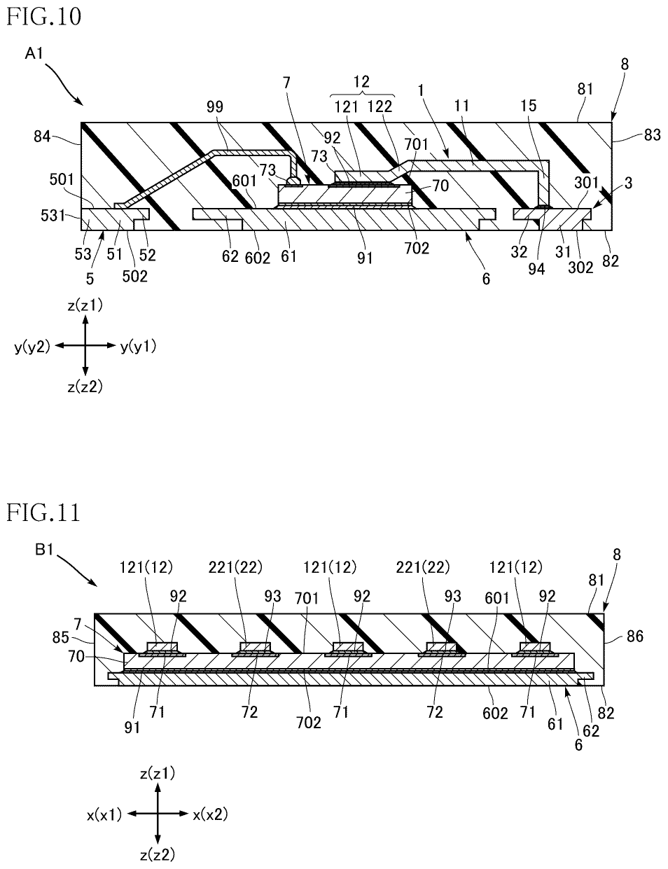

As shown in FIG. 1, FIG. 2, FIG. 8, and FIG. 10 to FIG. 12, the first connecting portion 121 of each of the plurality of first branch portions 12 of the first lead 1 is conductively bonded to the corresponding one of the first electrodes 71, via a second conductive bonding portion 92. The second conductive bonding portion 92 is, for example, formed of solder, Ag paste, sintered Ag, or sintered Cu. As shown in FIG. 1, FIG. 2, FIG. 9, FIG. 11, and FIG. 12, the second connecting portion 221 of each of the plurality of second branch portions 22 of the second lead 2 is conductively bonded to the corresponding one of the second electrodes 72, via a third conductive bonding portion 93. The third conductive bonding portion 93 is, for example, formed of solder, Ag paste, sintered Ag, or sintered Cu.

The third electrode 73 acts as the gate electrode. The number of pieces of the third electrode 73 is not limited, and may be one, or two or more. In the illustrated example, one third electrode 73 is provided. The third electrode 73 is located, for example, at one of the four corners of the element obverse face 701. In the illustrated example, the third electrode 73 is located close to the corner of the element obverse face 701 on the x2-side of the x-direction and the y2-side of the y-direction. In addition, the third electrode 73 is located on the y2-side of the y-direction, with respect to the first electrode 71 on the x2-side of the x-direction, out of the two first electrodes 71. The wire 99 is bonded to the third electrode 73, so that the third electrode 73 becomes electrically connected to the fifth lead 5, via the wire 99. Here, instead of the wire 99, an electrically conductive material formed of a metal plate may be employed, to make the third electrode 73 and the fifth lead 5 electrically connected to each other.

### Sealing Resin 8

The sealing resin 8 covers a part of each of the plurality of leads 1 to 6, the semiconductor element 7, and the wire 99, and is formed of an insulative material such as an epoxy resin. As shown in FIG. 1 to FIG. 11, the sealing resin 8 is formed in a rectangular cuboid shape, including a first face 81, a second face 82, a third face 83, a fourth face 84, a fifth face 85, and a sixth face 86.

The first face 81 is oriented to the z1-side of the z-direction. In the illustrated example, the first face 81 includes a flat face perpendicular to the z-direction. The second face 82 is oriented to the z2-side of the z-direction. In the illustrated example, the second face 82 includes a flat face perpendicular to the z-direction. The third face 83 is oriented to the y1-side of the y-direction. In the illustrated example, the third face 83 includes a flat face perpendicular to the y-direction. The fourth face 84 is oriented to the y2-side of the y-direction. In the illustrated example, the fourth face 84 includes a flat face perpendicular to the y-direction. The fifth face 85 is oriented to the x1-side of the x-direction. In the illustrated example, the fifth face 85 includes a flat face perpendicular to the x-direction. The sixth face 86 is oriented to the x2-side of the x-direction. In the illustrated example, the sixth face 86 includes a flat face perpendicular to the x-direction.

From the second face 82, the reverse face 602 of the island lead 6, the reverse face 302 of the third lead 3, the reverse face 402 of the fourth lead 4, and the reverse face 502 of the fifth lead 5 are exposed to the z2-side of the z-direction. The second face 82, the reverse face 602 of the island lead 6, the reverse face 302 of the third lead 3, the reverse face 402 of the fourth lead 4, and the reverse face 502 of the fifth lead 5 are flush with one another. However, one or more, or all of the reverse face 602 of the island lead 6, the reverse face 302 of the third lead 3, the reverse face 402 of the fourth lead 4, and the reverse face 502 may slightly protrude from the second face 82.

From the third face 83, the plurality of end faces 331 of the third lead 3 are exposed to the y1-side of the y-direction. The third face 83 and the plurality of end faces 331 of the third lead 3 are flush with one another. However, one or more, or all of the plurality of end faces 331 may slightly protrude from the third face 83.

From the fourth face 84, the fourth end face 241 of the second lead 2, the plurality of end faces 431 of the fourth lead 4, and the end face 531 of the fifth lead 5 are exposed to the y2-side of the y-direction. The fourth face 84, the fourth end face 241 of the second lead 2, the plurality of end faces 431 of the fourth lead 4, and the end face 531 of the fifth lead 5 are flush with one another. However, one or more, or all of the fourth end face 241 of the second lead 2, the plurality of end faces 431 of the fourth lead 4, and the end face 531 of the fifth lead 5 may slightly protrude from the fourth face 84.

From the fifth face 85, the first end face 131 of the first lead 1, the second end face 231 of the second lead 2, and the plurality of end faces 631 of the island lead 6 are exposed to the x1-side of the x-direction. The fifth face 85, the first end face 131 of the first lead 1, the second end face 231 of the second lead 2, and the plurality of end faces 631 of the island lead 6 are flush with one another. However, one or more, or all of the first end face 131 of the first lead 1, the second end face 231 of the second lead 2, and the plurality of end faces 631 of the island lead 6 may slightly protrude from the fifth face 85.

From the sixth face 86, the third end face 141 of the first lead 1, and the plurality of end faces 631 of the island lead 6 are exposed to the x2-side of the x-direction. The sixth face 86, the third end face 141 of the first lead 1, and the plurality of end faces 631 of the island lead 6 are flush with one another. However, one or more, or all of the third end face 141 of the first lead 1, and the plurality of end faces 631 of the island lead 6 may slightly protrude from the sixth face 86.

The semiconductor device A1 is mounted on a circuit board (not shown), using the reverse face 302, the reverse face 402, and the reverse face 502, exposed from the second face 82 of the sealing resin 8, as the mounting terminal. In other words, the face of the semiconductor device A1 on the z2-side of the z-direction, opposite to the z1-side to which the element obverse face 701 of the semiconductor element 7 is oriented, is used as the mounting surface. In addition, the reverse face 602 serves as a heat dissipation surface for releasing the heat from the semiconductor element 7.

Hereunder, the advantageous effects of the semiconductor device A1 will be described.

According to this embodiment, as shown in FIG. 12, the first width W11 of the first branch portion 12 is narrower than the second width W12. The first connecting portion 121 is conductively bonded to the first electrode 71. Accordingly, the current flows in the y-direction, in the first branch portion 12. This current becomes larger, as the current flows toward the first main portion 11 in the y-direction. The first branch portion 12, serving as the conduction path of the current, is wider on the side on which the first main portion 11 is located, in the y-direction. Therefore, the current concentration in the current path can be alleviated.

In the manufacturing process of the semiconductor device A1, the first branch portion 12 assumes a cantilever form, with one side supported by the first main portion 11. When the length of the first branch portion 12 in the y-direction increases, or the thickness thereof in the thickness direction z is reduced, the first branch portion 12 may warp as a whole, such that the distal end of the first branch portion 12 is shifted to the z2-side of the thickness direction z. In this embodiment, since the second width W12 is wider than the first width W11, the first branch portion 12 can be prevented from warping, and therefore the semiconductor device A1 can be more properly manufactured.

The first connecting portion 121 has the tapered shape, which becomes wider in the first direction x, toward the first basal portion 122 in the y-direction. Such a shape is advantageous in alleviating the current concentration. In this embodiment, in addition, the entirety of the first connecting portion 121 is formed in the tapered shape. Such a configuration further alleviates the current concentration.

In addition, the first basal portion 122 has the tapered shape. Such a configuration further facilitates the alleviation of the current concentration, and the prevention of the warp. The fourth width W21 of the second branch portion 22 is narrower than the fifth width W22. The second connecting portion 221 is conductively bonded to the second electrode 72. Accordingly, the current flows in the y-direction, in the second branch portion 22. This current becomes larger, as the current flows toward the second main portion 21 in the y-direction. The second branch portion 22, serving as the conduction path of this current, is wider on the side on which the second main portion 21 is located, in the y-direction. Therefore, the current concentration in the current path can be alleviated.

In the manufacturing process of the semiconductor device A1, the second branch portion 22 assumes a cantilever form, with one side supported by the first main portion 11. When the length of the second branch portion 22 in the y-direction increases, or the thickness thereof in the thickness direction z is reduced, the second branch portion 22 may warp as a whole, such that the distal end of the second branch portion 22 is shifted to the z2-side of the thickness direction z. In this embodiment, since the fifth width W22 is wider than the fourth width W21, the second branch portion 22 can be prevented from warping, and therefore the semiconductor device A1 can be more properly manufactured.

The second connecting portion 221 has the tapered shape, which becomes wider in the first direction x, toward the second basal portion 222 in the y-direction. Such a shape is advantageous in alleviating the current concentration. In this embodiment, in addition, the entirety of the second connecting portion 221 is formed in the tapered shape. Such a configuration further alleviates the current concentration.

In addition, the second basal portion 222 has the tapered shape. Such a configuration further facilitates the alleviation of the current concentration, and the prevention of the warp.

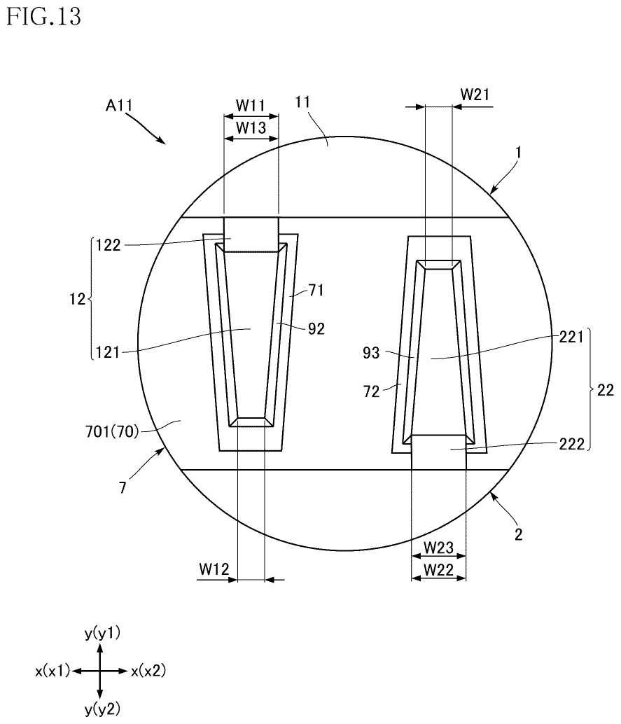

FIG. 13 to FIG. 20 illustrate other embodiments of the present disclosure. In these drawings, the elements same as or similar to those of the foregoing embodiment are given the same numeral. The configuration of each part in the embodiments and variations thereof may be combined as appropriate, unless technical contradiction arises.

### First Variation of First Embodiment

FIG. 13 illustrates a first variation of the semiconductor device A1. The semiconductor device A11 according to this variation is different from the semiconductor device A1, in the configuration of the first branch portion 12 and the second branch portion 22.

In this variation, the first width W11 and the third width W13 of the first branch portion 12 are the same. In other words, the first basal portion 122 has a constant width in the first direction x. Likewise, the fifth width W22 and the sixth width W23 of the second branch portion 22 are the same. In other words, the second basal portion 222 has a constant width in the first direction x.

The configuration according to this variation also alleviates the current concentration in the current path, and prevents the first branch portion 12 and the second branch portion 22 from warping, during the manufacturing process. Further, as may be understood from this variation, it is not mandatory that the first branch portion 12 and the first protruding portion 13 are formed in the continuous tapered shape as a whole.

### Second Variation of First Embodiment

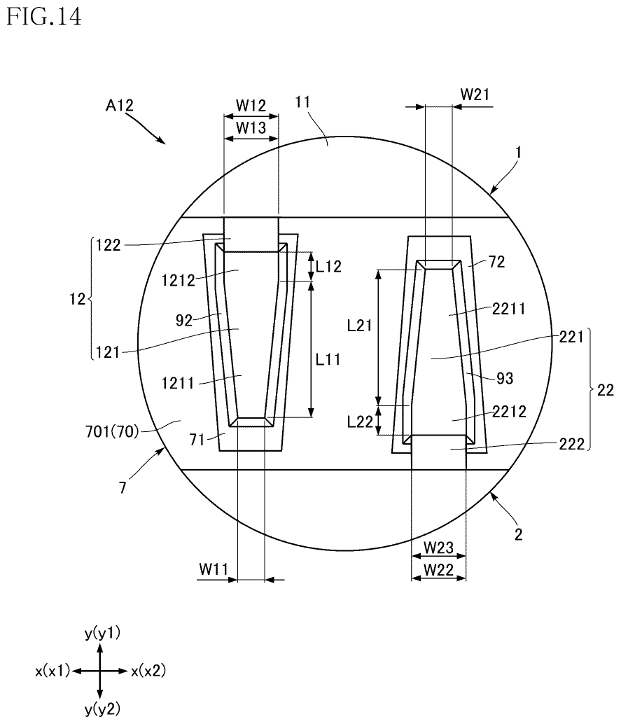

FIG. 14 illustrates a second variation of the semiconductor device A1. The semiconductor device A12 according to this variation is different from the foregoing examples, in the configuration of the first branch portion 12 and the second branch portion 22.

In this variation, the first basal portion 122 and the second basal portion 222 each have a constant width in the first direction x.

The first connecting portion 121 includes a first tapered portion 1211 and a first constant-width portion 1212.

The first tapered portion 1211 has a shape that becomes wider in the first direction x, in the direction from the distal end portion on the y2-side toward the first basal portion 122 (y1-side).

The first constant-width portion 1212 is interposed between the first tapered portion 1211 and the first basal portion 122. The first constant-width portion 1212 has a constant width in the first direction x. In the illustrated example, the width of the first constant-width portion 1212 in the first direction x is the same (or generally the same) as the width of the first basal portion 122 in the first direction x (second width W12, third width W13). A first length L11, corresponding to the length of the first tapered portion 1211 in the y-direction, is longer than a second length L12, corresponding to the length of the first constant-width portion 1212 in the y-direction.

The second connecting portion 221 includes a second tapered portion 2211 and a second constant-width portion 2212.

The second tapered portion 2211 has a shape that becomes wider in the first direction x, in the direction from the distal end portion on the y1-side toward the second basal portion 222 (y2-side). The second constant-width portion 2212 is interposed between the second tapered portion 2211 and the second basal portion 222. The second constant-width portion 2212 has a constant width in the first direction x. In the illustrated example, the width of the second constant-width portion 2212 in the first direction x is the same (or generally the same) as the width of the second basal portion 222 in the first direction x (fifth width W22, sixth width W23). A third length L21, corresponding to the length of the second tapered portion 2211 in the y-direction, is longer than a fourth length L22, corresponding to the length of the second constant-width portion 2212 in the y-direction.

The configuration according to this variation also alleviates the current concentration in the current path, and prevents the first branch portion 12 and the second branch portion 22 from warping, during the manufacturing process. Further, as may be understood from this variation, it is not mandatory that the first connecting portion 121 and the first basal portion 122 are exclusively formed of the tapered shape.

### Third Variation of First Embodiment

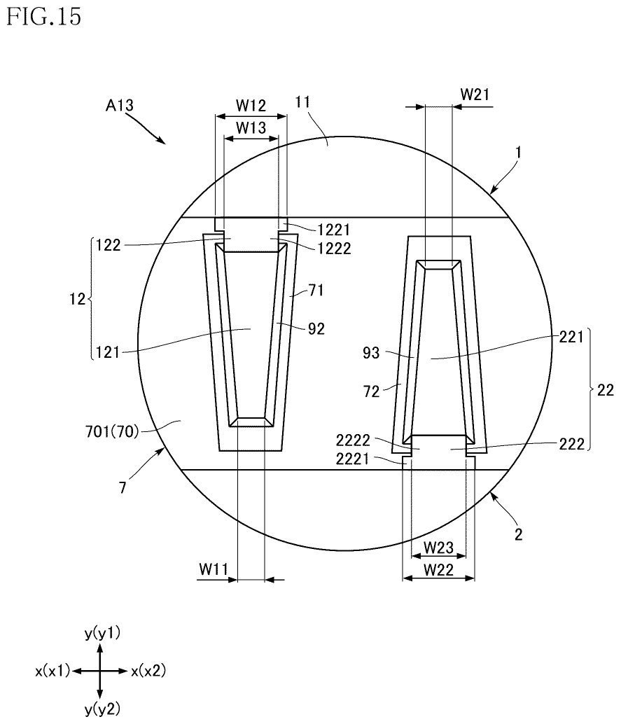

FIG. 15 illustrates a third variation of the semiconductor device A1. The semiconductor device A13 according to this variation is different from the foregoing examples, in the configuration of the first branch portion 12 and the second branch portion 22.

The first basal portion 122 according to this variation includes a first wide portion 1221 and a first narrow portion 1222. The first wide portion 1221 is wider in the first direction x than the first narrow portion 1222, and interposed between the first narrow portion 1222 and the first main portion 11. The first narrow portion 1222 is interposed between the first wide portion 1221 and the first connecting portion 121. In the illustrated example, the width of the first wide portion 1221 in the first direction x is defined as the second width W12, and the width of the first narrow portion 1222 in the first direction x is defined as the third width W13. The first wide portion 1221 is not overlapping with the first electrode 71, when viewed in the thickness direction z.

The second basal portion 222 according to this variation includes a second wide portion 2221 and a second narrow portion 2222. The second wide portion 2221 is wider in the first direction x than the second narrow portion 2222, and interposed between the second narrow portion 2222 and the second main portion 21. The second narrow portion 2222 is interposed between the first wide portion 2221 and the second connecting portion 221. In the illustrated example, the width of the second wide portion 2221 in the first direction x is defined as the fifth width W22, and the width of the second narrow portion 2222 in the first direction x is defined as the sixth width W23. The first wide portion 2221 is not overlapping with the second electrode 72, when viewed in the thickness direction z.

The configuration according to this variation also alleviates the current concentration in the current path, and prevents the first branch portion 12 and the second branch portion 22 from warping, during the manufacturing process. Further, as may be understood from this variation, the shape of the first basal portion 122 and the shape of the second basal portion 222 are in no way limited. Providing the first wide portion 1221 and the first wide portion 2221 further facilitates the alleviation of the current concentration in the current path, and the prevention of the warp of the first branch portion 12 and the second branch portion 22 during the manufacturing process. Further, the first wide portion 1221 is not overlapping with the first electrode 71, and the first wide portion 2221 is not overlapping with the second electrode 72, when viewed in the thickness direction z. Such a configuration further assures the insulation between the first wide portion 1221 and the first electrode 71, and the insulation between the first wide portion 2221 and the second electrode 72.

### Second Embodiment

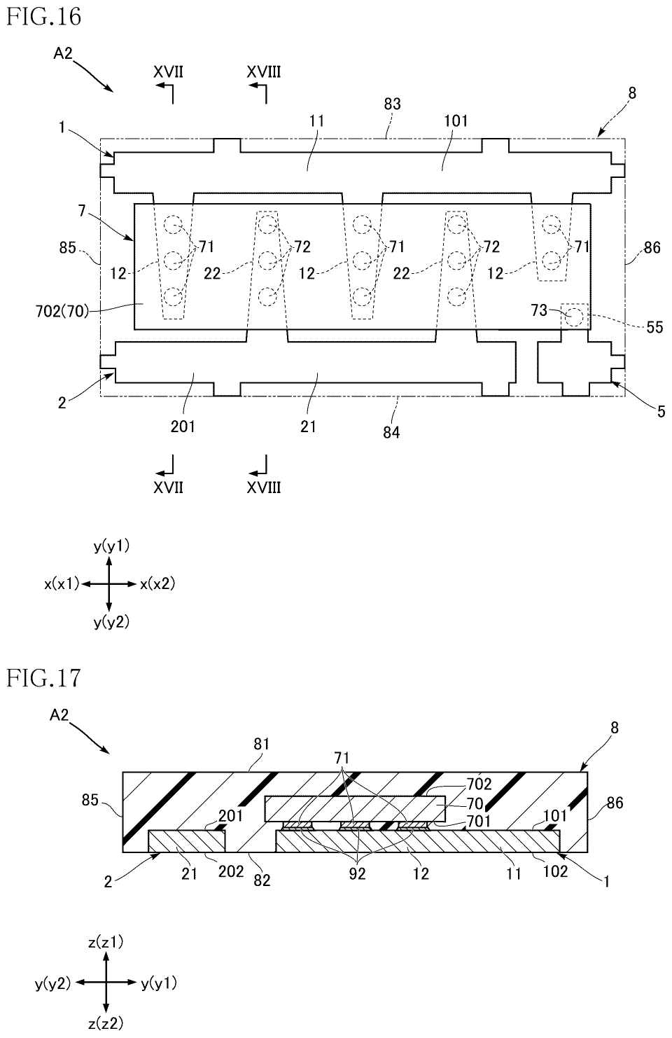

FIG. 16 to FIG. 18 illustrate a semiconductor device according to a second embodiment of the present disclosure. The semiconductor device A2 according to this embodiment includes the first lead 1, the second lead 2, the fifth lead 5, the semiconductor element 7, and the sealing resin 8.

The semiconductor element 7 according to this embodiment is mounted with the element obverse face 701 oriented to the z2-side of the z-direction, and the element reverse face 702 oriented to the z1-side of the z-direction. The plurality of first electrodes 71, the plurality of second electrodes 72, and the third electrode 73 are each constituted of a plurality of metal bumps. The plurality of first electrodes 71 each include a plurality of metal bumps (two or three, in the drawings) aligned along the y-direction, and constituting a set. A plurality of (three) sets of the first electrodes 71 are aligned along the first direction x. The plurality of second electrodes 72 each include a plurality of metal bumps (three in the drawings) aligned along the y-direction and constituting a set. A plurality of (two) sets of the second electrodes 72 are aligned along the first direction x. The plurality of sets of first electrodes 71 and the plurality of sets of second electrodes 72 are alternately aligned along the first direction x.

The first lead 1 includes an obverse face 101 and a reverse face 102. The obverse face 101 is oriented to the z1-side of the z-direction, and opposed to the element obverse face 701 of the semiconductor element 7. The reverse face 102 is oriented to the z2-side of the z-direction, and exposed from the second face 82 of the sealing resin 8. In this embodiment, the first lead 1 has a constant thickness in the z-direction.

The second lead 2 includes an obverse face 201 and a reverse face 202. The obverse face 201 is oriented to the z1-side of the z-direction, and opposed to the element obverse face 701 of the semiconductor element 7. The reverse face 202 is oriented to the z2-side of the z-direction, and exposed from the second face 82 of the sealing resin 8. In this embodiment, the second lead 2 has a constant thickness in the z-direction.

The respective shapes of the plurality of first branch portions 12 of the first lead 1, and the plurality of second branch portions 22 of the second lead 2, viewed in the z-direction are, for example, similar to those of the plurality of first branch portions 12 and the plurality of second branch portions 22 of the semiconductor device A1. However, the plurality of first branch portions 12 and the plurality of second branch portions 22 may have the same shape as those in the semiconductor devices A11, A12, and A13, or different shapes. The plurality of first branch portions 12 and the plurality of second branch portions 22 are located on the z2-side of the z-direction, with respect to the semiconductor element 7.

The plurality of first branch portions 12 are each conductively bonded to the corresponding set of the first electrode 71, via the second conductive bonding portion 92. The plurality of second branch portions 22 are each conductively bonded to the corresponding set of the second electrode 72, via the third conductive bonding portion 93.

The fifth lead 5 includes a third connecting portion 55. To the third connecting portion 55, the third electrode 73 is conductively bonded via a non-illustrated conductive bonding portion. One face of the fifth lead 5 is exposed from the second face 82 of the sealing resin 8.

In the semiconductor device A2 according to this embodiment, the semiconductor element 7 is flip-chip bonded to the first lead 1, the second lead 2, and the third lead 3. The reverse face 102 of the first lead 1, the reverse face 202 of the second lead 2, and the face of the fifth lead 5 (face exposed from the second face 82) serve as the mounting terminals, when the semiconductor device A2 is mounted on a circuit board (not shown).

The configuration according to this embodiment also alleviates the current concentration in the current path, and prevents the first branch portion 12 and the second branch portion 22 from warping, during the manufacturing process. Further, as may be understood from this embodiment, the bonding form between the first and second leads 1, 2, and the semiconductor element 7 is in no way limited.

### First Variation of Second Embodiment

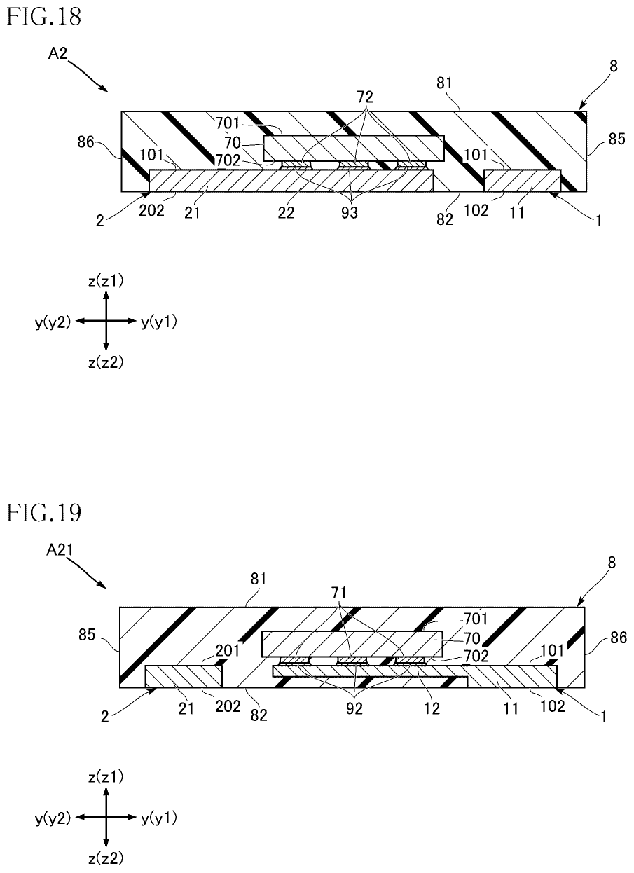

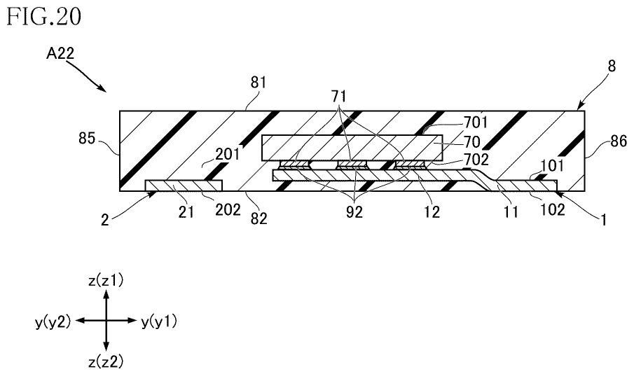

FIG. 19 illustrates a first variation of the semiconductor device A2. In the semiconductor device A21 according to this variation, the first branch portion 12 is thinner than the first main portion 11, in the first lead 1. The first branch portion 12 is not exposed from the second face 82 of the sealing resin 8, to the z2-side of the z-direction. In addition, the second branch portion 22 is thinner than the second main portion 21, in the second lead 2. The second branch portion 22 is not exposed from the second face 82 of the sealing resin 8, to the z2-side of the z-direction. The first lead 1 and the second lead 2 configured as above can be formed, for example, by etching a metal plate material from both sides in the z-direction.

The configuration according to this variation also alleviates the current concentration in the current path, and prevents the first branch portion 12 and the second branch portion 22 from warping, during the manufacturing process. Further, as may be understood from this variation, it is not mandatory that the first lead 1 and the second lead 2 each have a constant thickness.

### Second Variation of Second Embodiment

FIG. 20 illustrates a second variation of the semiconductor device A2. In the semiconductor device A22 according to this variation, the first branch portion 12 is located on the z1-side of the z-direction, with respect to the first main portion 11, in the first lead 1. The first branch portion 12 is not exposed from the second face 82 of the sealing resin 8, to the z2-side of the z-direction. The first main portion 11 and the first branch portion 12 have the same (or generally the same) thickness as each other, in the thickness direction z. In addition, in the second lead 2, the second branch portion 22 is located on the z1-side of the z-direction, with respect to the second main portion 21. The second branch portion 22 is not exposed from the second face 82 of the sealing resin 8, to the z2-side of the z-direction. The second main portion 21 and the second branch portion 22 have the same (or generally the same) thickness as each other, in the thickness direction z. The first lead 1 and the second lead 2 configured as above can be formed, for example, by bending a metal plate material.

The configuration according to this variation also alleviates the current concentration in the current path, and prevents the first branch portion 12 and the second branch portion 22 from warping, during the manufacturing process. Further, as may be understood from this variation, the first lead 1 and the second lead 2 may be bent in the thickness direction z.

The semiconductor device according to the present disclosure is not limited to the foregoing embodiments. The specific configuration of the semiconductor device according to the present disclosure may be modified in various manners. The present disclosure encompasses the embodiments that can be defined as the following clauses.

### Clause 1

A semiconductor device including:
a plurality of leads;
a semiconductor element; and
a sealing resin covering at least a part of the plurality of leads and the semiconductor element,
in which the plurality of leads include a first lead,
the semiconductor element includes an element obverse face oriented to one side and an element reverse face oriented to the other side, in a thickness direction, and a plurality of first electrodes arranged on the element obverse face along a first direction intersecting the thickness direction,
the first lead includes a first main portion, and a plurality of first branch portions extending from the first main portion in a second direction, intersecting the thickness direction and the first direction, and arranged along the first direction,
the first branch portion includes a first basal portion connected to the first main portion, and a first connecting portion conductively bonded to the first electrode, and
a first width corresponding to a width of a distal end portion of the first connecting portion in the first direction is narrower than a second width corresponding to a width of a boundary between the first basal portion and the first main portion in the first direction.

### Clause 2

The semiconductor device according to clause 1, in which the first connecting portion includes a first tapered portion that becomes wider in the first direction, in a direction from the distal end portion toward the first basal portion.

### Clause 3

The semiconductor device according to clause 2, in which the first connecting portion only includes the first tapered portion.

### Clause 4

The semiconductor device according to clause 2, in which the first connecting portion includes a first constant-width portion, interposed between the first tapered portion and the first basal portion.

### Clause 5

The semiconductor device according to clause 4, in which a first length, corresponding to a length of the first tapered portion in the second direction, is longer than a second length corresponding to a length of the first constant-width portion in the second direction.

### Clause 6

The semiconductor device according to clause 1, in which a third width, corresponding to a width in the first direction, of a boundary between the first basal portion and the first connecting portion, is equal to the second width.

### Clause 7

The semiconductor device according to clause 1, in which a third width, corresponding to a width in the first direction, of a boundary between the first basal portion and the first connecting portion, is narrower than the second width, and wider than the first width.

### Clause 8

The semiconductor device according to clause 7, in which the first basal portion includes a first wide portion and a first narrow portion, and
the first wide portion is wider in the first direction than the first narrow portion, and interposed between the first narrow portion and the first main portion.

### Clause 9

The semiconductor device according to any one of clauses 1 to 8, in which the plurality of leads include a second lead,
the semiconductor element includes a plurality of second electrodes aligned along the first direction on the element obverse face,
the plurality of first electrodes and the plurality of second electrodes are alternately aligned along the first direction,
the second lead includes a second main portion located on an opposite side of the first main portion in the second direction, across the plurality of first electrodes and the plurality of second electrodes, when viewed in the thickness direction, and a plurality of second branch portions extending from the second main portion in the second direction, and aligned along the first direction,
the second branch portion includes a second basal portion connected to the second main portion, and a second connecting portion conductively bonded to the second electrode, and
a fourth width corresponding to a width in the first direction, of a distal end portion of the second connecting portion, is narrower than a fifth width corresponding to a width in the first direction, of a boundary between the second basal portion and the second main portion.

### Clause 10

The semiconductor device according to clause 9, in which the second connecting portion includes a second tapered portion that becomes wider in the first direction, in a direction from the distal end portion toward the second basal portion.

Clause 11

The semiconductor device according to clause 10, in which the second connecting portion only includes the second tapered portion.

### Clause 12

The semiconductor device according to clause 10, in which the second connecting portion includes a second constant-width portion interposed between the second tapered portion and the second basal portion.

### Clause 13

The semiconductor device according to clause 12, in which a third length corresponding to a length of the second tapered portion in the second direction is longer than a fourth length corresponding to a length of the second constant-width portion in the second direction.

### Clause 14

The semiconductor device according to clause 9, in which a sixth width corresponding to a width in the first direction, of a boundary between the second basal portion and the second connecting portion, is equal to the fifth width.

### Clause 15

The semiconductor device according to clause 9, in which a sixth width corresponding to a width in the first direction, of a boundary between the second basal portion and the second connecting portion, is narrower than the fifth width, and wider than the fourth width.

### Clause 16

The semiconductor device according to clause 15, in which the second basal portion includes a second wide portion and a second narrow portion, and
the second wide portion is wider in the first direction than the second narrow portion, and interposed between the second narrow portion and the second main portion.

### Clause 17

The semiconductor device according to any one of clauses 1 to 16, in which the semiconductor element includes a GaN-HEMT element.

REFERENCE SIGNS
A1, A11, A12, A13, A2, A21, A22: semiconductor device

```
      1: first lead
      2: second lead
      3: third lead
      4: fourth lead
      5: fifth lead
      6: island lead
      7: semiconductor element
      8: sealing resin
    11: first main portion
    12: first branch portion
    13: first protruding portion
    14: third protruding portion
    15: first upright portion
    21: second main portion
    22: second branch portion
    23: second protruding portion
    24: fourth protruding portion
    25: second upright portion
    29: intermediate portion
    31: thick portion
    32: thin portion
    33: protruding portion
    41: thick portion
    42: thin portion
    43: protruding portion
    49: intermediate portion
    51: thick portion
    52: thin portion
    53: protruding portion
    55: third connecting portion
    61: thick portion
    62: thin portion
    63: protruding portion
    70: element main body
    71: first electrode
    72: second electrode
    73: third electrode
    81: first face
    82: second face
    83: third face
    84: fourth face
    85: fifth face
    86: sixth face
    91: first conductive bonding portion
    92: second conductive bonding portion
    93: third conductive bonding portion
    94: fourth conductive bonding portion
    95: fifth conductive bonding portion
    99: wire
  101: obverse face
  102: reverse face
  111: through hole
  121: first connecting portion
  122: first basal portion
  131: first end face
  141: third end face
  201: obverse face
  202: reverse face
  211: through hole
  221: second connecting portion
  222: second basal portion
  231: second end face
  241: fourth end face
  301: obverse face
  302: reverse face
  331: end face
  401: obverse face
  402: reverse face
  431: end face
  501: obverse face
  502: reverse face
  531: end face
  601: obverse face
  602: reverse face
  631: end face
  701: element obverse face
  702: element reverse face
1211: first tapered portion
1212: first constant-width portion
1221: first wide portion
1222: second narrow portion
2211: second tapered portion
2212: second constant-width portion
2221: first wide portion
2222: second narrow portion
W11: first width
W12: second width
W13: third width
W21: fourth width
W22: fifth width
W23: sixth width
    x: first direction
    y: second direction
    z: thickness direction
```

1. A semiconductor device comprising:
a plurality of leads;
a semiconductor element; and
a sealing resin covering at least a part of the plurality of leads and the semiconductor element,
wherein the plurality of leads include a first lead,
the semiconductor element includes an element obverse face oriented to one side and an element reverse face oriented to the other side, in a thickness direction, and a plurality of first electrodes arranged on the element obverse face along a first direction intersecting the thickness direction,
the first lead includes a first main portion, and a plurality of first branch portions extending from the first main portion in a second direction, intersecting the thickness direction and the first direction, and arranged along the first direction,
the first branch portion includes a first basal portion connected to the first main portion, and a first connecting portion conductively bonded to the first electrode, and
a first width corresponding to a width of a distal end portion of the first connecting portion in the first direction is narrower than a second width corresponding to a width of a boundary between the first basal portion and the first main portion in the first direction.

2. The semiconductor device according to claim 1, wherein the first connecting portion includes a first tapered portion that becomes wider in the first direction, in a direction from the distal end portion toward the first basal portion.

3. The semiconductor device according to claim 2, wherein the first connecting portion only includes the first tapered portion.

4. The semiconductor device according to claim 2, wherein the first connecting portion includes a first constant-width portion, interposed between the first tapered portion and the first basal portion.

5. The semiconductor device according to claim 4, wherein a first length, corresponding to a length of the first tapered portion in the second direction, is longer than a second length corresponding to a length of the first constant-width portion in the second direction.

6. The semiconductor device according to claim 1, wherein a third width, corresponding to a width in the first direction, of a boundary between the first basal portion and the first connecting portion, is equal to the second width.

7. The semiconductor device according to claim 1, wherein a third width, corresponding to a width in the first direction, of a boundary between the first basal portion and the first connecting portion, is narrower than the second width, and wider than the first width.

8. The semiconductor device according to claim 7, wherein the first basal portion includes a first wide portion and a first narrow portion, and
the first wide portion is wider in the first direction than the first narrow portion, and interposed between the first narrow portion and the first main portion.

9. The semiconductor device according to claim 1, wherein the plurality of leads include a second lead,
the semiconductor element includes a plurality of second electrodes aligned along the first direction on the element obverse face,
the plurality of first electrodes and the plurality of second electrodes are alternately aligned along the first direction,
the second lead includes a second main portion located on an opposite side of the first main portion in the second direction, across the plurality of first electrodes and the plurality of second electrodes, when viewed in the thickness direction, and a plurality of second branch portions extending from the second main portion in the second direction, and aligned along the first direction,
the second branch portion includes a second basal portion connected to the second main portion, and a second connecting portion conductively bonded to the second electrode, and
a fourth width corresponding to a width in the first direction, of a distal end portion of the second connecting portion, is narrower than a fifth width corresponding to a width in the first direction, of a boundary between the second basal portion and the second main portion.

10. The semiconductor device according to claim 9, wherein the second connecting portion includes a second tapered portion that becomes wider in the first direction, in a direction from the distal end portion toward the second basal portion.

11. The semiconductor device according to claim 10, wherein the second connecting portion only includes the second tapered portion.

12. The semiconductor device according to claim 10, wherein the second connecting portion includes a second constant-width portion interposed between the second tapered portion and the second basal portion.

13. The semiconductor device according to claim 12, wherein a third length corresponding to a length of the second tapered portion in the second direction is longer than a fourth length corresponding to a length of the second constant-width portion in the second direction.

14. The semiconductor device according to claim 9, wherein a sixth width corresponding to a width in the first direction, of a boundary between the second basal portion and the second connecting portion, is equal to the fifth width.

15. The semiconductor device according to claim 9, wherein a sixth width corresponding to a width in the first direction, of a boundary between the second basal portion and the second connecting portion, is narrower than the fifth width, and wider than the fourth width.

16. The semiconductor device according to claim 15, wherein the second basal portion includes a second wide portion and a second narrow portion, and
the second wide portion is wider in the first direction than the second narrow portion, and interposed between the second narrow portion and the second main portion.

17. The semiconductor device according to claim 1, wherein the semiconductor element includes a GaN-HEMT element.
